(19) United States
(12) Patent Application Publication
(10) Pub. No.: US 2006/0244983 A1
(43) Pub. Date: Nov. 2, 2006

(54) Fast color mapping using primary adjustment with gamut adaptation

(76) Inventor: Huanzhao Zeng, Vancouver, WA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/118,038

(22) Filed: Apr. 29, 2005

(51) Int. Cl. G03F 3/08

(52) U.S. Cl. 358/1.9; 358/518

(57) ABSTRACT

Disclosed are embodiments of a system and method for rendering colors between color devices. The method includes establishing a source color gamut for a source device and the source color gamut has a white point, a black point, and primary points. The method also includes establishing a destination color gamut for a destination device, and the destination color gamut has a white point, a black point, and primary points. White and black point adaptation is performed to adapt the white and black points of the source color gamut to the white and black points of the destination color gamut, respectively. Neutral points from the source color gamut are processed to the destination color gamut without applying gamut mapping. Aimed primary points are determined from the adapted white and black points and from the source and destination primary points, the destination gamut, and color preference. Colors on the source gamut surface are mapped to the aimed gamut surface by geometrically reshaping a combination of the source primary points and the adapted white and black points to a combination of aimed primary points and the adapted white and black points. Points on each plane connected by the white and black points and a primary are then processed. Finally, the remaining interior points of the source gamut are processed by interpolation.

### CROSS-REFERENCE TO RELATED APPLICATIONS

This patent application is related to U.S. patent application Ser. No. XX/XXX,XXX filed on even date herewith entitled FAST PRIMARY MAPPING AND GAMUT ADAPTATION TO CONSTRUCT THREE DIMENSIONAL LOOK-UP TABLES having docket number 200500911-1, commonly assigned to the same assignee as the present invention, and hereby incorporated by reference herein.

### BACKGROUND

The present invention relates generally to the field of color-image processing and more particularly to a system and method of adapting from one color gamut to another without gamut mapping every node in the color gamut.

Any color imaging device has its limit in reproducing color such that it cannot reproduce all color that exists. The range of color that a device produces is known as the color gamut of the device. Different devices have different color gamuts. In order to preserve similar color appearance when color is transferred from one device into another, such as from monitor to printer, gamut mapping is typically used. Many gamut-mapping methods and algorithms have been developed, and such methods improve the quality of color transformation in cross-media color reproductions.

In device color characterization, a multiple-dimensional lookup table is typically generated. For example, a three dimensional sRGB to CMYK lookup table can be generated for the transformation from monitor sRGB to printer CMYK. In an International Color Consortium (ICC) color management system, an ICC profile is generated for the color transformation for each setting mode of a color device. A three dimensional lookup table for the transformation from profile connection space (“PCS”), which is CIE LAB or XYZ in a specified illuminant and viewing condition, to CMYK for each rendering intent is included in an ICC profile for a printer CMYK ICC profile.

Gamut-mapping algorithms are typically used to gamut map colors point-by-point, that is, they gamut map every node of a lookup table or every pixel of an image. Because of the heavy computation involved in gamut mapping, the gamut mapping is generally not fast enough for real-time device color characterization. Such point-by-point gamut mapping will cause a “bottle-neck” for color management module implementation. Furthermore, in some instances point-by-point processing in gamut mapping can ignore the preservation of relative relationship of neighbor color, which is significant for preserving color appearance.

For these and other reasons, a need exists for the present invention.

### SUMMARY

Exemplary embodiments of the present invention include a system and method for rendering colors between color devices. One embodiment of the method includes establishing a source color gamut for a source device and the source color gamut has a white point, a black point, and primary points. The method also includes establishing a destination color gamut for a destination device, and the destination color gamut has a white point, a black point, and primary points. White and black point adaptation is performed to adapt the white and black points of the source color gamut to the white and black points of the destination color gamut, respectively. Neutral points from the source color gamut are processed to the destination color gamut. Aimed primary points are determined from the adapted white and black points and from the source and destination primary points, the destination gamut, and color preference. An aimed gamut surface is mapped by geometrically reshaping a combination of the source primary points and its white and black points to a combination of aimed primary points and its white and black points. Interior points of the source gamut surface are processed.

### BRIEF DESCRIPTION OF THE DRAWINGS

FIG. 1 illustrates a processing system with a source color device and a destination color device.

FIG. 2 illustrates a gamut comparison between sRGB and SWOP CMYK in three-dimensional CIE L*a*b* color space.

FIG. 3 illustrates a gamut comparison between sRGB and SWOP CMYK in two-dimensional CIE a*-b* color space.

FIG. 4 illustrates a hue slice of a sRGB gamut and SWOP CMYK gamut from FIG. 2.

FIG. 5A illustrates a three-dimensional gamut represented in a device RGB color space.

FIG. 5B illustrates a three-dimensional gamut represented in an L-S-H color space derived from the RGB color space of FIG. 5A.

FIG. 6A illustrates two sets of primaries (RYGCBM and rygcbm) in a chrominance C1-C2 coordinate system.

FIG. 6B illustrates adaptation of a source gamut slice to an aimed gamut slice in accordance with one embodiment.

FIG. 7 illustrates a user interface used in one embodiment to adjust weighting parameters.

FIG. 8 illustrates a constant hue gamut slice plotting lightness against chroma.

FIG. 9A illustrates a difference of a portion of gamut due to the differences of two neighbor primaries between a source gamut and an aimed gamut.

FIG. 9B illustrates the adaptation of the source primaries to the aimed primaries of FIG. 9A.

FIG. 10 illustrates a triangle consisting of a white, a black, and a primary node with separation point Q.

FIG. 11 is a flow chart illustrating one embodiment of a spring-primary mapping process in accordance with the present invention

### DETAILED DESCRIPTION

In the following Detailed Description, reference is made to the accompanying drawings, which form a part hereof, and in which is shown by way of illustration specific embodiments in which the invention can be practiced. It is to be understood that other embodiments can be utilized and structural or logical changes can be made without departing from the scope of the present invention. The following Detailed Description, therefore, is not to be taken in a limiting sense, and the scope of the present invention is defined by the appended claims.

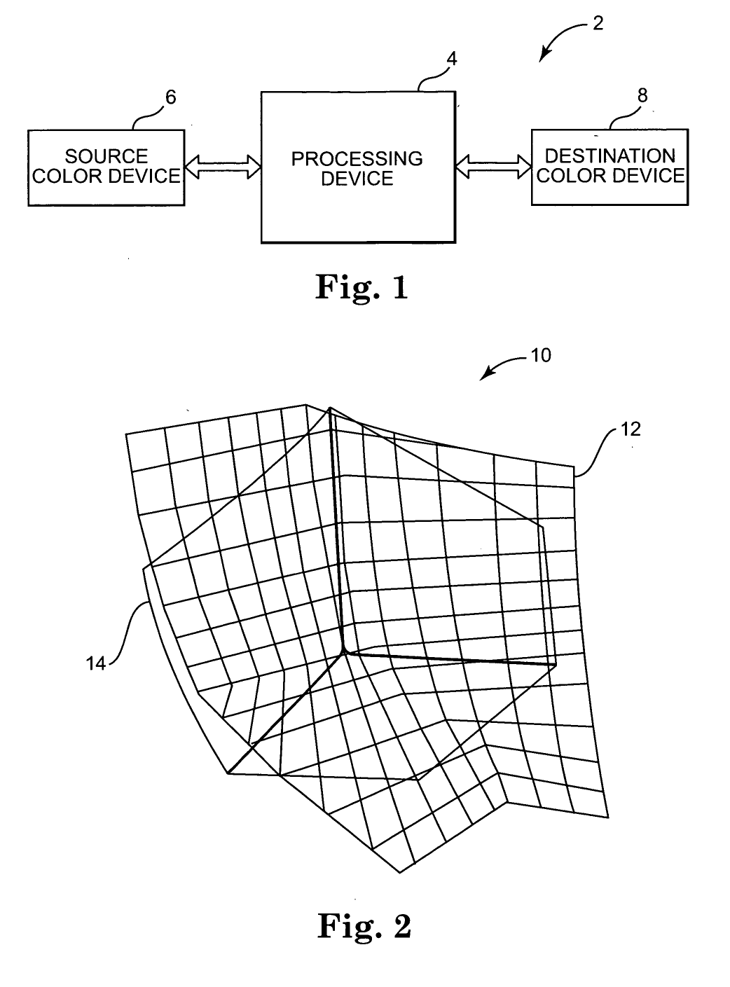

FIG. 1 illustrates processing system 2. Processing system 2 includes a processing device 4 and source color device 6 and destination color device 8. In one example, source and destination color devices 6 and 8 are a color monitor and a digital color printer, respectively. In other examples, source and destination color devices 6 and 8 are each color monitors, each color printers, a scanner and a monitor, a scanner and a printer and combinations of these and other color devices. In operation, processing device 4 facilitates color transformation of images from a source color device to destination color device.

Each of source and destination color devices 6 and 8 has a color gamut that defines the range of color that the device produces. In one example, the color gamuts of source and destination color devices 6 and 8 are different from each other. Consequently, in order to preserve similar color appearance when color is transferred from one device into another, for example from a monitor to a printer, the color gamut of each device is considered. The process of color matching, in which differences in color gamuts between the source device and the destination device are taken into consideration, is gamut mapping.

FIG. 2 is a three-dimensional representation of the color gamuts of source and destination color devices 6 and 8. In one example, CIE L*a*b* color space 10 illustrates a source color gamut 12 for and a destination color gamut 14. In one case, source color gamut 12 is for a color monitor and is represented in sRGB color space. In one case, destination color gamut 14 is for a digital color printer and is represented in SWOP CMYK color space. In one example, processing device 4 uses these different color gamuts 12 and 14 to transfer an image from the monitor to the printer.

Transforming colors from one device into another via gamut mapping is typically performed in a device-independent color space, such CIELAB, CIECAM02 JAB, or CIECAM97s JAB. FIG. 2 illustrates that the sRGB source gamut 12 is much larger than the SWOP destination gamut 14, but it does not encompass the entire SWOP gamut. Gamut mapping moves colors in the source device to fit into the destination device.

Traditional gamut mapping maps colors point by point using a three dimensional lookup table. For example, to generate a 17×17×17 three-dimensional lookup table for the transformation from sRGB to CMYK, each of 17×17×17 (or 4913) nodes goes through a gamut mapping in order to map each node from the sRGB gamut to the CMYK gamut. This process involves extensive computation that, in some applications, demands significant processing resources.

As is evident in FIG. 2, although color gamuts 12 and 14 share many points in common, many other color points that are producible in source color gamut 12 are not producible in destination color gamut 14 (for example, see the lower-right portion of color gamut 12 in FIG. 2). Similarly, many color points that are producible in destination color gamut 14 are not producible in source color gamut 12 (for example, see the lower-left portion of color gamut 14 in FIG. 2). To produce colors that are out of the destination gamut, gamut compression is performed. To use the portion of the destination gamut that is out of the source gamut, gamut expansion is performed. Without hue adjustments, some primary colors cannot be printed (in the case of a color printer destination device) with a reasonable lightness and chroma for a given destination printer. Thus, many gamut mapping methods perform gamut mapping in two steps: hue rotation followed by gamut mapping to map colors from the source gamut to the destination gamut.

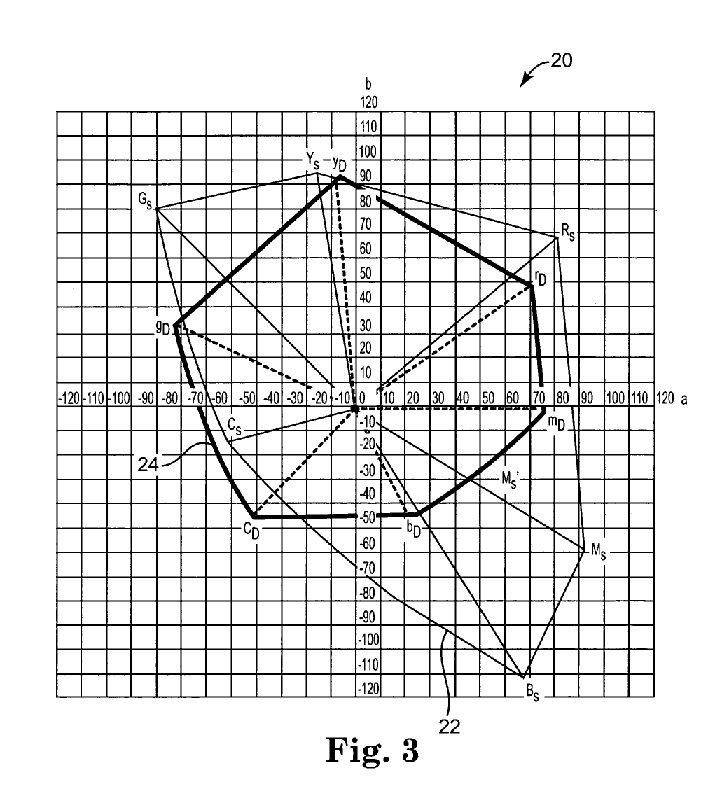

FIG. 3 is a two-dimensional representation of a gamut comparison between sRGB and SWOP CMYK in CIE a*-b* color space. In other words, it is the illustration of FIG. 2 ignoring the L* coordinate. In one example, CIE a*b* color space 20 illustrates a planar slice 22 from the source color gamut 12 and a planar slice 24 from the destination color gamut 14. Planar slice 22 from the source color gamut 12 illustrates primary colors of the source: green (G_{S}), yellow (Y_{S}), red (R_{S}), magenta (M_{S}), blue (B_{S}), and cyan (C_{S}). Similarly, planar slice 24 from the destination color gamut 14 illustrates primary colors of the destination: green (G_{D}), yellow (Y_{D}), red (R_{D}), magenta (M_{D}), blue (B_{D}), and cyan (C_{D}).

If the sRGB magenta hue within the source color gamut 12 (represented by Mₛ in FIG. 3) is not rotated towards the reddish direction, the capability of magenta within the destination color gamut 14 (represented by Mₛ' in FIG. 3) will not be fully used. Thus, in FIG. 3, Mₛ is mapped to Mₛ'. An sRGB reddish magenta that has lower chroma than that of the sRGB magenta can be mapped to a printed color that has higher chroma than that of the printed color corresponded to the sRGB magenta.

Hue rotation during primary mapping better preserves the relative color relationship among the gamut surface colors and high saturated colors. It is performed prior to the gamut mapping. In addition to hue adjustment, lightness adjustment is also used to better preserve the relative color relationship among color gamuts, such as between source color gamut 12 and destination color gamut 14.

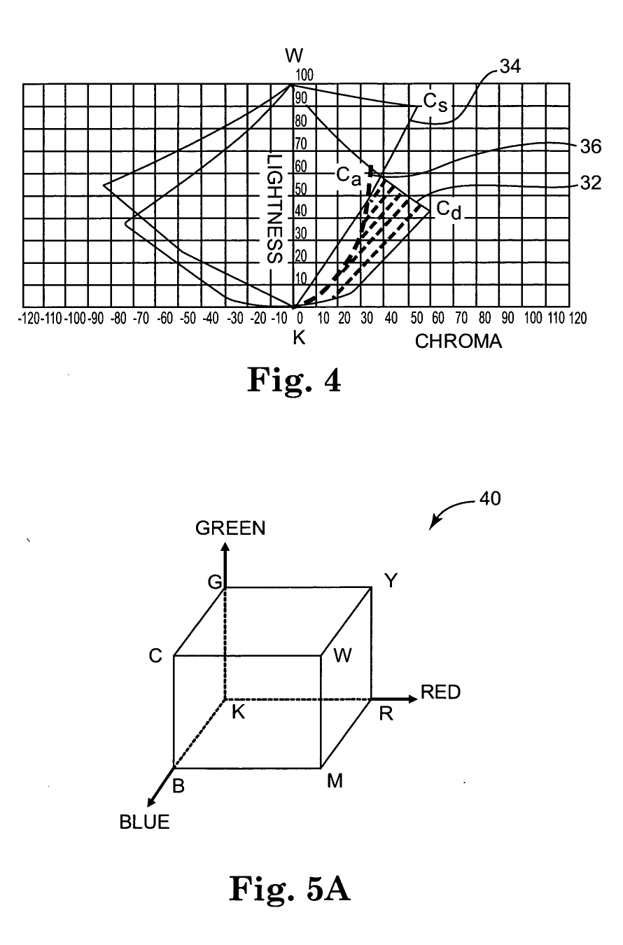

FIG. 4 illustrates a constant hue slice of sRGB gamut and SWOP CMYK gamut from FIG. 2. Lightness is in the vertical direction of the figure, and chroma in the horizontal direction. Constant hue slice 34 is from the source color gamut 12 and constant hue slice 32 is from the destination color gamut 14. The black point (K) is adjusted to zero, and white point (W) is illustrated above the black point (K). The lightness of the source cusp (Cₛ) can be reduced to map this point to the destination cusp (C_{d}) so that the source white-to-Cₛ color ramp can be mapped to the destination white-to-C_{d} color ramp and the source black-to-Cₛ color ramp can be mapped to the destination black-to-C_{d} color ramp nicely.

While this kind of mapping is typically appropriate for text and computer graphics, it typically induces too much distortion for images. An aimed point, such as Cₐ in FIG. 4, can be chosen as a destination mapping primary for an image/photo rendering intent. Because the most saturated source point Cₛ is mapped to Cₐ, the printable colors from Cₐ to C_{d} can not be used. The portion of the destination color gamut encompassed by curves or lines from the white point (W) to Cₐ to the black point (K) to the white point (W) can be used as the aimed gamut. The portion of the destination gamut illustrated in dotted lines is not used with this mapping.

While the lightness adjustment can be performed during the gamut mapping, it can also be accomplished in a separated primary adjustment step prior to the gamut mapping, or be done by the joined operation of the primary adjustment and gamut mapping.

One embodiment of the present invention provides a “spring-primary” gamut mapping apparatus and method. Spring-primary gamut mapping combines the primary adjustment and gamut mapping in a single step and well adapts the three-dimensional source gamut into a three-dimensional destination gamut in a three-dimensional manner such that it is easy to visually maintain the color-to-color relative relationship. Furthermore, gamut mapping is performed for only a small percentage of nodes in a lookup table, thus it takes significantly less time to generate a lookup table than methods that involve gamut mapping all the nodes of a lookup table. This basic concept for primary mapping and gamut adaptation is referred to as a spring-primary mapping process, and will be described in more detail below.

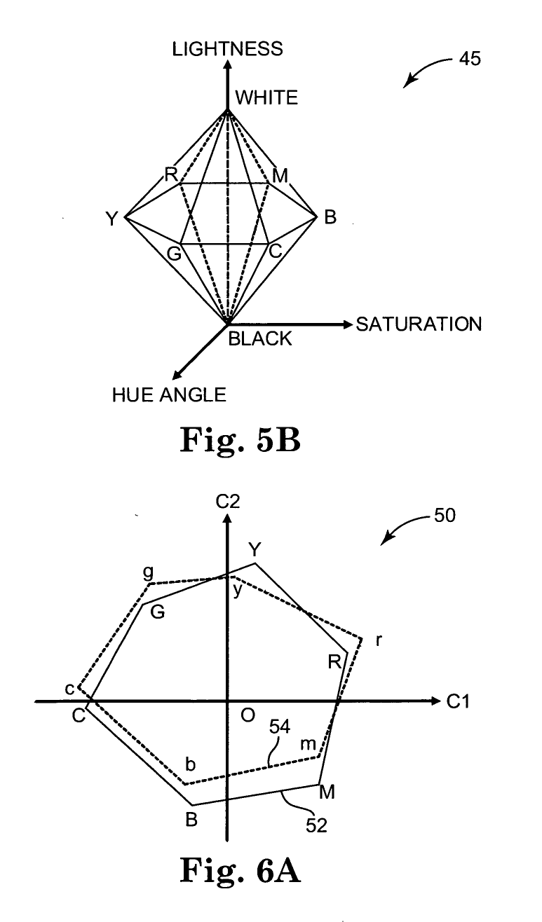

To visualize the gamut mapping in one embodiment of the invention, a three-dimensional gamut in a device RGB color space is transferred to a three-dimensional gamut in an L-S-H (lightness-saturation-hue) color space. FIG. 5A illustrates a three-dimensional gamut 40 of an RGB color space. Black (K) and white (W) nodes are illustrated, as are the primary colors blue (B), green (G), cyan (C), red (R), magenta (M), and yellow (Y). These nodes each comprise the eight corners of the illustrated rectangular three-dimensional source gamut 40. While more points are usually required to construct a gamut accurately, these eight points approximately represent a device gamut.

FIG. 5B illustrates a three-dimensional gamut 45 in an L-S-H color space derived from the RGB color space of FIG. 5A. Again, black (K) and white (W) nodes are illustrated, as are the primary colors blue (B), green (G), cyan (C), red (R), magenta (M), and yellow (Y). Here, these nodes each comprise the eight corners of the illustrated three-dimensional gamut 45.

For a three-dimensional 17×17×17 sRGB lookup table, the indexes of each of the 4913 nodes are denoted as (r, g, b), where r, g, and b are integers from 0 to 16. In this way, the indexes of the eight corner nodes are:

K (black): (0, 0, 0);

B (blue): (0, 0, 16);

G (green): (0, 16, 0);

C (cyan): (0, 16, 16);

R (red): (16, 0, 0);

M (magenta): (16, 0, 16);

Y (yellow): (16, 16, 0); and

W (white); (16, 16, 16).

When the indexes of an sRGB color (r, g, b) are changed gradually from the black point (r=g=b=0) to the white point (r=g=b=16) with r=g=b, the color changes gradually from black to gray to white. If the color mapping of the white and black points of sRGB to the white and black of a destination device, such as a printer, in a device-independent color space are known, and the tone mapping curve is known, gamut mapping for each of these seventeen points is avoided.

When the indexes of an sRGB color (r, g, b) are changed from white (16, 16, 16) to red (16, 0, 0), that is, r=16, and g and b are changed gradually from g=b=16 to g=b=0, the color changes gradually in the red ramp from white (W) to the red primary (R). Again, since the transition relationship (or relative relationship) of these sRGB colors is known, gamut mapping for all seventeen points is avoided and only the two end points (the white point and the red primary) are performed. The remaining points can be computed and mapped using a more efficient method.

A similar approach can be applied to other group of colors, such as the color ramps of W-to-G, W-to-B, W-to-Y, W-to-M, W-to-Y, K-to-R, K-to-G, K-to-B, K-to-C, K-to-M, and K-to-Y.

In one embodiment of the invention, a lookup table for the transformation from a source color space to a destination color space, which is based on the relative color relationship of neighbor nodes, is generated by gamut mapping for only a small portion of points. This method provides a more efficient approach to map color points from the source gamut to the destination gamut than gamut mapping each of the points from one color device gamut to another.

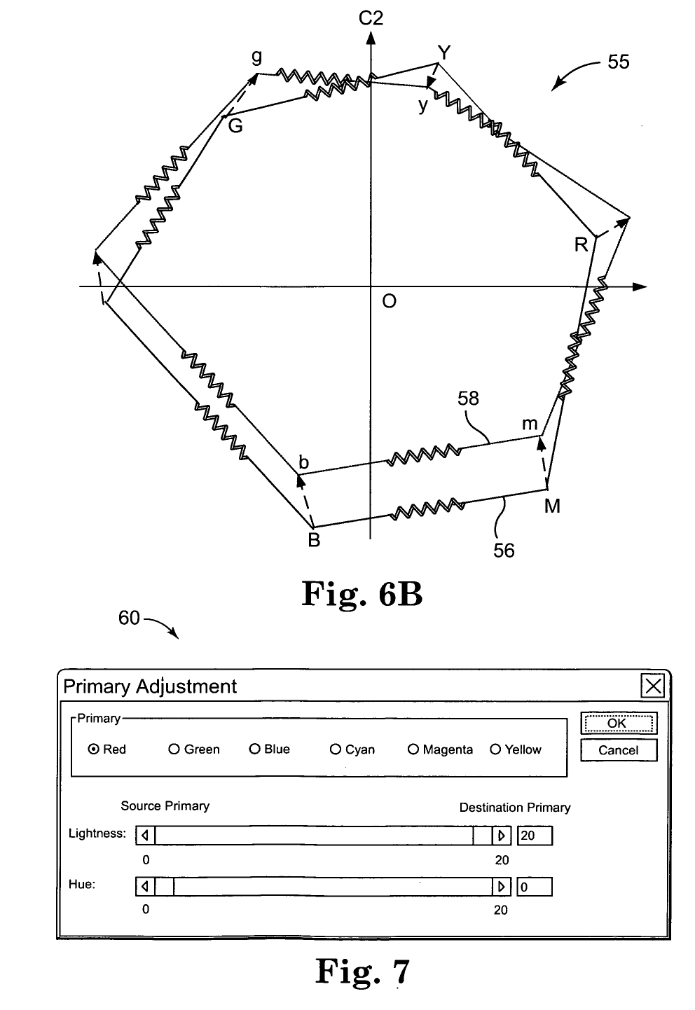

FIG. 6A illustrates two sets of primary gamuts in a chrominance C1-C2 coordinate system. In one embodiment, a*-b* of CIELAB color space 50 illustrates a planer source gamut slice 52 (having primary points RYGCBM) and a planer destination gamut slice 54 (having primary points rygcbm), each of which ignores the lightness channel. Primary colors blue (B), green (G), cyan (C), red (R), magenta (M), and yellow (Y) are illustrated in source gamut slice 52, and primary colors blue (b), green (g), cyan (c), red (r), magenta (m), and yellow (y) are also illustrated in destination gamut slice 54. As is evident from the illustration, planer source gamut slice 52 and planer destination gamut slice 54 do not line up because the primary colors or each have differing hue angles. In another embodiment, two sets of primaries can also be illustrated in A-B of the CIECAM JAB color space.

In the illustrated color space 50, the distance between two primary color nodes Y and R in source gamut slice 52, that is, the length of YR, is typically different than the distance between two primary color nodes y and r in destination gamut slice 54, that is, the length of yr. In this way, if point R in source gamut slice 52 is mapped to point r in destination gamut slice 54 (pull R to r), point Y can not be mapped to point y without changing the length of YR or of yr.

FIG. 6B illustrates how source gamut slice 56 is adapted to aimed gamut slice 58. First, each of the six primary points RYGCBM from source gamut slice 56 are adapted to each of the six primary points rygcbm in aimed gamut slice 58. After moving the six primary points, all interior points, which are on each of the lengths between the primary points, are adapted to the new shape by geometrical mapping. In FIG. 6B this geometrical mapping is illustrated by springs or coils on each of the lengths between the primary points. In this way, it can be visualized that each of the lengths between the primary points are stretched or contracted in order to fit into the aimed gamut slice 58.

The spring-primary mapping process for primary mapping and gamut adaptation will be described in more detail below with exemplary embodiments. For the exemplary embodiments described below, gamut mapping will be denoted in the LAB color space, although one skilled in the art will understand that gamut mapping is also performed in other lightness-chrominance color space, such as CIELAB, CIELUV, CIECAM97s Jab, or CIECAM02 Jab color space.

In one embodiment, the first step in the spring-primary mapping process is to perform white point and black point adaptation. For perceptual preference mapping, the source white point (W) is mapped to the destination white point (w), and the source black point (K) is mapped to the destination black point (k). A white point adaptation method (such as Von Kries transformation or other advanced color appearance modeling) is applied for the white point adaptation. A black point adjustment method is applied to map the source black point to the destination black point. The white point and black point adaptation are performed for all colors.

White point and black point adaptation can be performed in CIE XYZ space, a color corrected RGB color space, or in other color space. In addition, a tone mapping or contrast mapping method can be applied for tone adjustment. Other preference adjustments can also be applied. During the white point and black point adjustment, all colors are adjusted accordingly.

In one embodiment, the next step in the spring-primary mapping process, after the white point and black point adaptation is performed, is to process neutral points, that is, the points along the line between the white point and black points (the vertical line in FIG. 5B). All neutral nodes in a lookup table (for example, nodes for R=G=B in an sRGB lookup table) are computed by one-dimensional interpolation instead of by gamut mapping. For example, in one embodiment, the following linear interpolation equations are applied to compute output color values:

$${L}_{ia} = {L}_{ka} + ( \frac{{L}_{wa} - {L}_{ka}}{{L}_{ws} - {L}_{ks}} ) \cdot ( {L}_{is} - {L}_{ks} )$$

$${A}_{ia} = {A}_{ka} + ( \frac{{A}_{wa} - {A}_{ka}}{{A}_{ws} - {A}_{ks}} ) \cdot ( {A}_{is} - {A}_{ks} )$$

$${B}_{ia} = {B}_{ka} + ( \frac{{B}_{wa} - {B}_{ka}}{{B}_{ws} - {B}_{ks}} ) \cdot ( {B}_{is} - {B}_{ks} )$$

In the above linear interpolation equations, (Lᵢₛ, Aᵢₛ, Bᵢₛ) and (Lᵢₐ, Aᵢₐ, Bᵢₐ) are the LAB values of a source neutral color and its corresponding aimed output mapped color;

(L_{ws}, A_{ws}, B_{ws}) and (L_{wa}, A_{wa}, B_{wa}) are LAB values of the source white point and the destination white point (they are actually the same with a complete white point adaptation); and

(Lₖₛ, Aₖₛ, Bₖₛ) and (Lₖₐ, Aₖₐ, Bₖₐ) are LAB values of the source black point and the destination black point (they are the same after the black point adjustment).

If the chrominance of the neutral axis is zero (i.e. A=B=0 for color in the neutral axis), Aᵢₐ and Bᵢₐ are not computed by above equations. Instead, A and B are simple assigned with zero.

In an alternative embodiment, a distance based interpolation, described by the distance equations below, is used instead:

$${r}_{w} = \frac{1}{{D}_{iw}}$$

$${r}_{k} = \frac{1}{{D}_{ik}}$$

$${L}_{ia} = \frac{{L}_{wa} \cdot {r}_{w} + {L}_{ka} \cdot {r}_{k}}{{r}_{w} + {r}_{k}}$$

$${A}_{ia} = \frac{{A}_{wa} \cdot {r}_{w} + {A}_{ka} \cdot {r}_{k}}{{r}_{w} + {r}_{k}}$$

$${B}_{ia} = \frac{{B}_{wa} \cdot {r}_{w} + {B}_{ka} \cdot {r}_{k}}{{r}_{w} + {r}_{k}} ,$$

where D_{iw} is the distance or color difference between a neutral point and the white point in the source color space, and Dᵢₖ is the distance or color difference between a neutral point and the black point in the source color space.

For a 17×17×17 three-dimensional RGB lookup table, the indexes of the neutral nodes from W (the white point) to K (the black point) are: (16, 16, 16), (15, 15, 15), (14, 14, 14), (13, 13, 13), (12, 12, 12), (11, 11, 11), (10, 10, 10), (9, 9, 9), (8, 8, 8), (7, 7, 7), (6, 6, 6), (5, 5, 5), (4, 4, 4), (3, 3, 3), (2, 2, 2), (1, 1, 1), and (0, 0, 0).

In one embodiment, the next step in the spring-primary mapping process, after processing neutral points, is determining aimed primaries of the gamut surface. Aimed primaries are determined before primary mapping. The lightness and hue angle of each aimed primary are determined by following weighting equations:
L_{aimed}=w_{L}·L_{source}+(1−w_{L})·L_{destination}
h_{aimed}=wₕ·h_{source}+(1−wₕ)·h_{destination}

where L_{aimed}, L_{source}, and L_{destination} are the aimed lightness, the source lightness, and the destination lightness of a primary, respectively; where h_{aimed}, h_{source}, and h_{destination} are the aimed hue angle, the source hue angle, and the destination hue angle of the same primary, respectively; where w_{L} and wₕ are a weighting parameter for lightness and hue angle, respectively. In one embodiment, the w_{L} and wₕ values are between 0 and 1.

The weighting parameters for lightness and hue angle w_{L} and wₕ can be adjusted in order to optimize the destination primaries. In one embodiment, user interface 60, illustrated in FIG. 7, is provided to adjust weighting parameters. Via user interface 60, weighting parameters for each aimed primaries (Red, Green, Blue, Cyan, Magenta, and Yellow) can be adjusted by first clicking an appropriate primary color (Red is illustrated as selected in the example in FIG. 7) and then sliding one slider associated with lightness and one slider associated with hue. In the illustrated example, the slider position 0 corresponds to a weight of 1.0 (using the source primary as the aimed primary for the lightness or the hue angle), and the slider position 20 corresponds to a weight of 0 (using the destination primary as the aimed primary for the lightness or the hue angle). In this way, a determination is made for each of the primaries.

The aimed lightness (L_{aimed}) and the aim hue angle (h_{aimed}) or the weights w_{L} and wₕ can be determined by algorithms automatically. For example, they can be determined based on rendering intents (e.g. different aims are determined between photographic mapping and graphic mapping). The user adjustments can be provided for fine-tuning.

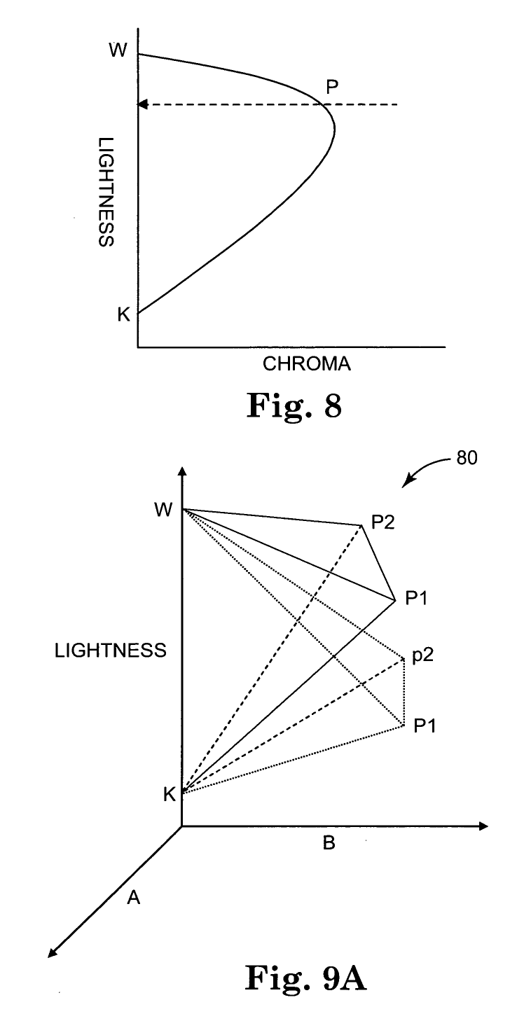

After lightness (L_{aimed}) and hue angle (h_{aimed}) of an aimed primary are determined, the chroma of the aimed primary is computed by finding the maximum chroma value of a color with lightness=L_{aimed} and hue angle=h_{aimed} in the destination gamut, i.e. the aimed primary is the point in the destination gamut surface that has lightness=L_{aimed} and hue angle=h_{aimed}. This can be done by gamut mapping in the constant hue angle=h_{aimed} and constant lightness=L_{aimed} as illustrated in FIG. 8. FIG. 8 illustrates a constant hue gamut slice, with lightness in the vertical direction and chroma in the horizontal direction. K is the adapted black point, and W is the adapted white point. In this h_{aimed} hue angle, the gamut mapping search the maximum chroma in a constant lightness L_{aimed} as shown on the dashed line. The maximized chroma point P is located as the aimed primary.

The chrominance A and B of LAB color gamut can be converted from LCh by:
A=C·cos(h)
B=C·sin(h)
where C is chroma and h is hue angle.

This process is then repeated for each primary, such that all six aimed primaries are determined using gamut mapping.

If the weighting parameter for both lightness and hue angle for a primary are 0, the aimed primary is the destination primary, and no gamut mapping is required to search the aimed primary point P.

In one embodiment, the next step in the spring-primary mapping process, after the aimed primaries are determined, is performing geometrical gamut reshaping in order to map the source gamut to the aimed gamut. Where the weighting parameter for lightness and hue angle corresponds to 0, then the aimed gamut is also the destination gamut.

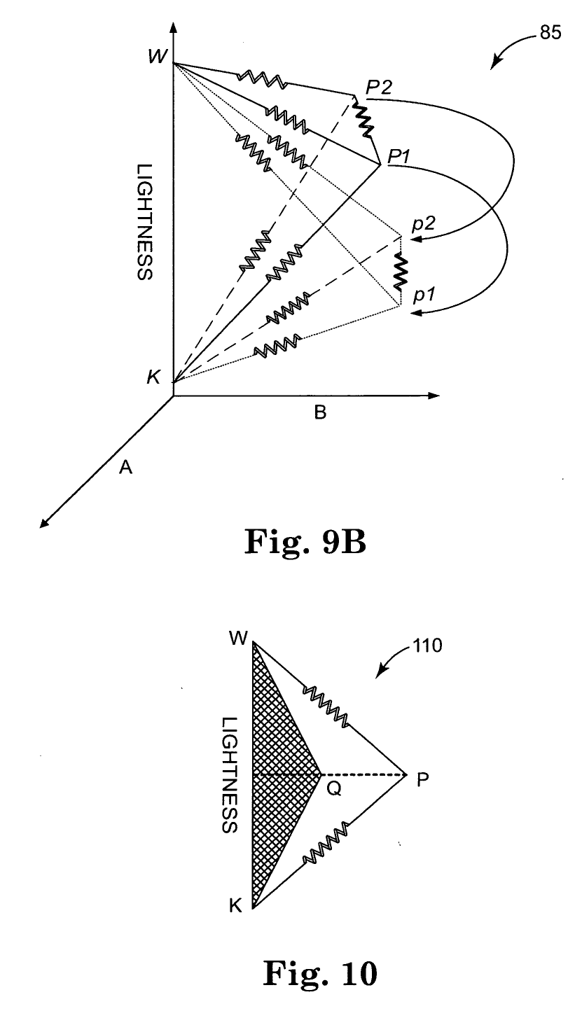

FIG. 9A illustrates a portion or sub-gamut of each gamut set 80, which is composed by the white point (W), the black point (K), and two neighbor primaries. A source sub-gamut is the tetrahedron KP1P2W (solid lines), and an aimed sub-gamut is the tetrahedron Kp1p2W (dotted lines). The lightness is in the vertical direction and chrominance A and B are in the horizontal direction. The black point (K) and white point (W) of are the adapted black and white points. P1 and P2 are two source neighbor primaries, and p1 and p2 are two corresponding aimed primaries. In FIG. 9A, the tetrahedron K-P1-P2-W is a portion of a three-dimensional device color gamut illustrated in FIG. 5B. The tetrahedron K-P1-P2-W is the source gamut that is then mapped into an aimed gamut represented by the tetrahedron K-p1-p2-W (p1 is the aimed primary corresponding to source primary P1, and p2 is the aimed primary corresponding to source primary P2). In this way, source primary P1 is mapped to aimed primary p1, and source primary P2 is mapped to aimed primary p2.

FIG. 9B illustrates a conceptual view 85 of how each line connecting each of two points in the tetrahedron K-P1-P2-W (solid lines) is an elastic string (or a spring), except the WK line. Similarly, each line connecting each of two points in the tetrahedron K-p1-p2-W (dotted lines) is an elastic string (or a spring), except the WK line. Since the WK line has been mapped by white and black point adaptations and tone mapping, it is not included in the gamut reshaping process. The remaining segments of the tetrahedron, however, are reshaped.

In this way, with this geometrical gamut reshaping process P1 is pulled to p1, and P2 is pulled to p2, such that all points along the tetrahedron W-P2-P1-K are adjusted accordingly based on a geometrical mapping process to maintain the overall geometrical relationship. Thus, the source gamut is reshaped to the aimed gamut. The overall effect is that each source primary is mapped to its corresponding aimed primary and the source gamut is closely reshaped to the aimed gamut. By this step, all points on each line of the source gamut are mapped (or moved) to the corresponding line of the aimed gamut, and all points on the source gamut surface (points on the triangles WP1P2 and KP1P1) are mapped (or moved) to the aimed gamut surface (the triangles Wp1p2 and Kp1p2) according to the geometrical reshaping process.

Because the sub-gamut represented by four points (W, K and two primaries) only approximately represent the sub-gamut of a device gamut, some point on the aimed gamut surface (triangles Wp1p2 and Kp1p2) can be slightly out of the destination gamut surface, and some points intended to be in the destination gamut surface might not be exactly on the destination gamut surface. Gamut mapping or other fine tuning methods are applied to adjust the source gamut surface points to the destination gamut.

Although the interior points of the sub-gamut can also be reshaped from the source gamut to the aimed gamut accordingly in this step, they are processed in a later step.

This primary mapping and reshaping is done for each of six primary sections, that is, for each of the tetrahedrons formed by the combination of the white and black points with two neighboring primaries. In this way, there is the tetrahedron W-R-Y-K, the tetrahedron W-Y-G-K, the tetrahedron W-G-C-K, the tetrahedron W-C-B-K, the tetrahedron W-B-M-K, and the tetrahedron W-M-R-K. Once this process is complete for each primary section, the entire source gamut is closely reshaped to the aimed gamut.

In this way, the elastic strings or springs illustrated in FIG. 9B can be envisioned on of the eighteen lines that connect each of the six primaries to a neighbor primary and that connect each primary to each of the white and black points (see FIG. 5B). Thus, eighteen springs are used: six of them are used to connect the white point to each of the six primaries; another six are used to connect the black point to each of the six primaries; and the remaining six are used to connect each primary to its neighbor primaries.

Because only eight points are used in this process (black point, white point, and six primary points) to determine how to reshape the gamut, the adjusted gamut is not exactly fitted in the destination gamut. To closely fit the source gamut to the destination gamut, more gamut surface points can be used so that we could use more springs to reshape the gamut. However, the more points are used, the higher the complexity in geometrical mapping. Using only these eight points to determine how to reshape the gamut in some cases gives a good approximation and significantly decreases processing time and demands.

Furthermore, instead of adding more control points to map the source gamut to the destination gamut, a post gamut mapping step is used in one embodiment to fine-tune gamut surface colors so that the source gamut fits into the destination gamut. Because the reshaped gamut is already closely fitted into the destination gamut, a simple and fast gamut mapping method can be used to fine-tune the color mapping. And only the points on or closed to the destination gamut surface are fine-tuned.

In one embodiment, the next step in the spring-primary mapping process, after the geometrical reshaping, is processing the interior points, that is, those nodes on the interior of the gamut surface. At this step, all nodes on the gamut surface of a three-dimensional lookup table have been mapped to the destination gamut. However, none of the interior nodes have been mapped by this step, except for the nodes on the neutral line (that is, nodes with r=g=b in an RGB lookup table). In order to process these interior nodes, six interior triangles are established. Referring to FIG. 5B, there are six triangles, each of which is composed of the white point (W), the black point (K), and a primary (P).

Such an interior triangle 110 is illustrated in FIG. 10, consisting of W, K, and P (a primary). In addition, a dotted line from P toward the middle of the neutral line between W and K has been added. An interior separation point Q is then added on that line. In some embodiments, P will be outside the destination gamut. In this way, interior separation point Q is selected such that is far enough inside the destination gamut that a non-adjusted triangle region WQK (the shaded area in FIG. 10) is defined within the interior triangle WKP in which no gamut mapping (compression or expansion) is performed. In other words, each node on the non-adjusted triangle WQK is mostly or all inside the destination gamut. Even in situations where a few nodes can be out of the destination gamut, they typically are close to the gamut surface.

For nodes on the non-adjusted triangle WQK, no color adjustment and gamut mapping is performed. In this way, the source LAB color of each node in this non-adjusted region is taken as the output LAB color. In this way, using this step of the spring-primary mapping process avoids gamut mapping for all of these nodes on the non-adjusted triangle WQK, thereby saving significant processing resources and time.

For nodes on the adjusted region of W-P-K-Q-W (the non-shaded area of interior triangle WKP in FIG. 10), an interpolation method is applied to compute the output LAB values. For example, a one dimensional interpolation similar to the method described earlier relating to processing neutral points can be applied to compute LAB values for nodes between Q and P. For the remaining points on the WPK plane, geometrical reshaping can be applied to adjust colors (fixing points W, Q, and K, and shaping point P). In another embodiment, these points are interpolated by a distance-based interpolation using three or more points on the triangle boundary lines of the region (WQ, QP, and PW on the triangle WQP, or KQ, QP, and PK on the triangle KQP).

In addition to processing nodes for each of the interior six triangles connected by W, K, and a primary, more such triangles can be processed. For example, a multitude of such interior triangles composed of W (white point), K (black point), and an edge point (that is, a point on a line connected by two neighbor primaries) can also be processed.

In one embodiment, the final step in the spring-primary mapping process, after processing the interior points of selected planes, is processing all remaining points. With the prior steps in the process, all gamut surface nodes and some interior nodes in a three-dimensional lookup table have been mapped to the destination gamut. The rest of the nodes in a lookup table are interpolated in three-dimensional manner. For each node, six points can be used for interpolation (six-weight interpolation). These six points are found from six directions relative to the point to be processed: up, down, left, right, front, and back. By searching each of the six directions, a point in each direction that has been mapped to the destination gamut and is closest to the point to be process is used for interpolation. The weight for each point is computed based on the distance of the point to the point to be processed (the closer the distance, the smaller the weight). The distance can be replaced by a color difference metric using a color difference formula (for example, ΔE₉₄).

For each point that has been mapped from the source LAB to the destination LAB, an interpolation method (for example, tetrahedral interpolation) is applied to map the LAB into the destination device color space.

In this way, the spring-primary mapping process avoids gamut mapping each node from a source color gamut to a destination color gamut, thereby providing a faster method of transformation of colors from a source color space to a destination color space.

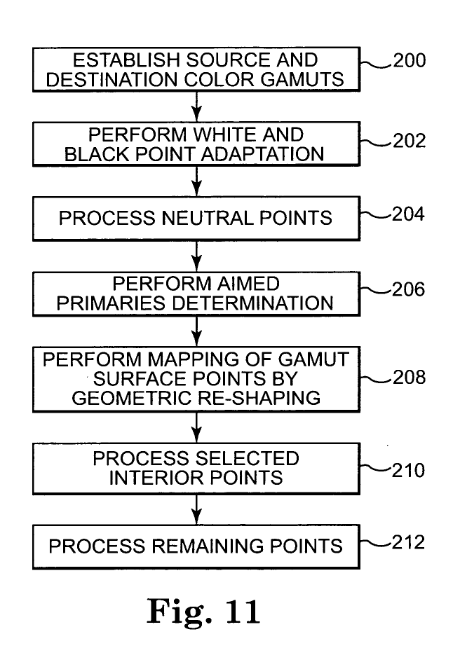

FIG. 11 is a flow chart illustrating one embodiment of transformation of images from a source color device to destination color device using the spring-primary mapping process in accordance with the present invention. At step 200, color gamuts are established for a source device and for a destination device. A device-independent color space (denoted LAB) is used for gamut representation and gamut mapping. This LAB color space can be CIELAB, CIELuv, CIECAM97s JAB, CIECAM02 JAB, etc. In one embodiment, the source device is a color monitor and the source color gamut is established by converting the RGB color space into LAB. In one embodiment, the destination device is a color printer and the destination color gamut is established in LAB converted from the CMYK color space.

At step 202, white point and black point adaptation is performed. For perceptual preference mapping, the source white point (W) is mapped to the destination white point (w), and the source black point (K) is mapped to the destination black point (k) in this step. The tone appearance adjustment and or color preference adjustment can be performed.

At step 204, neutral points of the color gamuts are processed. In this step, all the points along the line between the white point and black points are processed from the source to the destination gamut. In one case, linear interpolation equations are applied to compute output color values, and in another case a distance based interpolation is used.

Next, at step 206 the aimed primaries of the gamut surface are processed. In one embodiment, aimed or destination primaries are determined before the primary mapping. In one case, the lightness and hue angle of each aimed primary are determined using weighting equations. In another case, the lightness and hue angle of each aimed primary are determined by rendering intent based modeling. After lightness and hue angle of each of the primaries are determined, the chroma of the aimed primary is computed in one case by gamut mapping in a constant hue angle and constant lightness. This process is used for each primary, such that all six aimed primaries are determined using gamut mapping.

Next, at step 208 gamut reshaping is performed in order to map the source gamut to the aimed or destination gamut. With this gamut reshaping process, each pair of source primaries, along with the white and black points, are constructed as a tetrahedron, the source primaries of which are pulled to the corresponding destination primaries, thereby adjusting the points along the lines and planes connecting the primaries as well. In this way, the source gamut is reshaped to the aimed gamut. The overall effect is that each source primary is mapped to its corresponding aimed primary and the source gamut is closely reshaped to the aimed gamut. In this step, all source gamut surface points are mapped to the aimed gamut surface, and finally to the destination gamut with minor adjustment.

Next, at step 210 selected interior points of the gamut are processed. In processing these interior nodes, interior triangles are established consisting of W (white point), K (black point), and P (one primary point), or in some embodiments, consisting of W (white point), K (black point), and one point on an edge point between two primaries. From each of these interior triangles, an interior separation point Q (that is, Q is within the aimed gamut and within the destination gamut) is established. From this interior separation point Q, a non-adjusted triangle region WQK is defined. No gamut mapping is performed on the interior points, which are those within the non-adjusted triangle region WOK, such that the source LAB color of each node in this non-adjusted region is taken as the output LAB color. For the remaining points on the WPK plane, geometrical reshaping a distance-based interpolation is applied to adjust colors.

Finally, at step 212 remaining interior points of the gamut are processed. These remaining nodes are interpolated in three-dimensional manner. For each node, six points can be used for interpolation, such that a six-weight interpolation is used. The weight for each point is computed based on the distance of the point to the point to be processed (the closer the distance, the smaller the weight).

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of transferring colors between color devices, the method comprising:
establishing a source color gamut for a source device, the source color gamut having a white point, a black point, and primary points;
establishing a destination color gamut for a destination device, the destination color gamut having a white point, a black point, and primary points;
performing white and black point adaptation such that the source white point is mapped to the destination white point and the source black point is mapped to the destination black point, thereby establishing adapted white and black points;
processing neutral points from the source color gamut to the destination color gamut;
determining aimed primary points on an aimed gamut surface of an aimed gamut from the source and destination primary points, the destination gamut, and color preference;
mapping the source gamut to the destination gamut by geometrically reshaping a combination of the source primary points and the adapted white and black points to a combination of aimed primary points and the adapted white and black points; and
processing interior points of the aimed gamut surface.

2. The method of claim 1, wherein geometrically reshaping further comprises:
constructing a source sub-gamut comprising a pair of source primaries and the adapted white and black points connected by lines;
constructing an aimed sub-gamut comprising a pair of corresponding aimed primaries and the adapted white and black points connected by lines;
pulling the pair of source primaries to the corresponding aimed primaries while adjusting points along lines connecting the primaries and the adapted white and black points such that the source gamut is reshaped to the aimed gamut.

3. The method of claim 2, wherein geometrically reshaping further comprises adjusting points on a gamut surface of the source sub-gamut to fit into a gamut surface of the aimed gamut.

4. The method of claim 3 further comprising adjusting points on the gamut surface of the aimed sub-gamut to fit into a gamut surface of the destination gamut.

5. The method of claim 2 further comprising constructing the source and aimed sub-gamuts as tetrahedrons.

6. The method of claim 1 further comprising providing a red point (R), a green point (G), a blue point (B), a cyan point (C), a magenta point (M), and a yellow point (Y) as the source primary points and providing a red point (r), a green point (g), a blue point (b), a cyan point (c), a magenta point (m), and a yellow point (y) as the aimed primary points.

7. The method of claim 1 further comprising determining aimed primary points before mapping to the aimed gamut surface.

8. The method of claim 7 further comprising determining lightness and hue angle of each aimed primary point in determining aimed primary points.

9. The method of claim 8, further comprising determining lightness and hue angle of each aimed primary point using weighting equations.

10. The method of claim 9, further comprising computing chroma of each aimed primary point by gamut mapping in a constant hue angle and constant lightness.

11. The method of claim 1 further comprising defining a non-adjusted region inside the aimed gamut surface such that all interior points in the non-adjusted region are taken from the source gamut and placed in the aimed destination gamut without performing gamut mapping in the processing of interior points.

12. The method of claim 11, wherein processing interior points further comprises:
establishing interior triangles each comprising the adapted white point, the adapted black point, and one aimed primary point; and
determining a separation point within the interior triangles thereby defining the non-adjusted region.

13. The method of claim 12 further comprising processing any remaining points inside the gamut surface using three-dimensional interpolated.

14. A system for rendering colors between color devices, the system comprising:
a source color device having a source color gamut with a white point, a black point, and primary points;
a destination color device having a destination color gamut with a white point, a black point, and primary points; and
a processing device coupled between the source color device and the destination color device;
wherein the processing device is configured to perform white and black point adaptation such that the source white point is mapped to the destination white point and the source black point is mapped to the destination black point, thereby establishing adapted white and black points, to determine aimed primary points from a combination of the source and destination primary points, the destination gamut, and color preference, to map a source gamut surface to an aimed gamut surface by geometrically reshaping a combination of the source primary points and the adapted white and black points to a combination of aimed primary points and the adapted white and black points, and to process interior points of the source gamut surface.

15. The system of claim 14, wherein the processing device is further configured to map the source gamut surface to a destination gamut by geometrically reshaping.

16. The system of claim 15, wherein the processing device is further configured to construct a source sub-gamut comprising a pair of source primaries and the adapted white and black points connected by lines, to construct an aimed sub-gamut comprising a pair of corresponding aimed primaries and the adapted white and black points connected by lines, and to pull the pair of source primaries to the corresponding aimed primaries while adjusting points along the lines connecting the primaries and the adapted white and black points and points on the gamut surface triangles such that the source gamut is reshaped to the aimed gamut.

17. The system of claim 15, wherein the source color device is a color monitor and wherein the destination color device is a color printer.

18. The system of claim 17, wherein the source color gamut and wherein the destination color gamut is established in a luminance-chrominance color space, such as CIE LAB, CIE Luv, CIECAM07s JAB, CIECMA02 JAB color space.

19. The system of claim 15, wherein the primary points include a red point (R), a green point (G), a blue point (B), a cyan point (C), a magenta point (M), and a yellow point (Y) and wherein the aimed primary points include a red point (r), a green point (g), a blue point (b), a cyan point (c), a magenta point (m), and a yellow point (y).

20. The system of claim 15, wherein the processing device is further configured to perceptually map the source white point to the destination white point and the source black point to the destination black point.

21. The system of claim 15, wherein aimed primary points are determined before mapping the source gamut surface points.

22. The system of claim 21, wherein the processing device is further configured to determine lightness and hue angle of each aimed primary point.

23. The system of claim 22, wherein the processing device is further configured to determine lightness and hue angle of each aimed primary point using weighting equations.

24. The system of claim 23, wherein the processing device is further configured to compute chroma of each aimed primary point by gamut mapping in a constant hue angle and constant lightness.

25. The system of claim 15, wherein the processing device is further configured to processing interior points by defining a non-adjusted region inside the aimed gamut surface such that all interior points in the non-adjusted region are taken from the source gamut and placed in the aimed destination gamut without performing gamut mapping.

26. The system of claim 25, wherein the processing device is further configured to process interior points by:
establishing interior triangles each comprising the adapted white point, the adapted black point, and one aimed primary point; and
determining a separation point within the interior triangles thereby defining the non-adjusted region.

27. The system of claim 26, wherein the processing device is further configured to processes any remaining points inside the gamut surface using three-dimensional interpolation.

28. A method of transferring colors between color devices, the method comprising:
establishing a source color gamut for a source device, the source color gamut having a white point, a black point, and primary points;
establishing a destination color gamut for a destination device, the destination color gamut having a white point, a black point, and primary points;
performing white and black point adaptation to establish adapted white and black points;
determining aimed primary points from the adapted white and black points and from the source and destination primary points and from color preference;
constructing a source sub-gamut comprising a pair of source primaries and the adapted white and black points connected by lines;
constructing an aimed sub-gamut comprising a pair of corresponding aimed primaries and the adapted white and black points connected by lines;
pulling the pair of source primaries to the corresponding aimed primaries while adjusting points along the lines connecting the primaries and the adapted white and black points and adjusting the points on a source sub-gamut surface connected by these lines such that the source gamut is reshaped to the aimed gamut forming an aimed gamut surface and finally mapped to the destination gamut; and
processing interior points of the source gamut surface.

29. The method of claim 28 further comprising processing neutral points from the source color gamut to the destination color gamut.

30. The method of claim 29 further comprising processing all points along a line between the white point and black points from the source to the destination gamut using linear interpolation equations.

31. The method of claim 29, further comprising processing all points along a line between the white point and the black point from the source to the destination gamut using distance based interpolation.

32. The method of claim 31 further comprising defining a non-adjusted region inside the aimed gamut surface such that all interior points in the non-adjusted region are taken from the source gamut and placed in the aimed destination gamut without performing gamut mapping in the processing of interior points.

33. The method of claim 32, wherein processing interior points further comprises:
establishing interior triangles each comprising the adapted white point, the adapted black point, and one aimed primary point; and
determining a separation point within the interior triangles thereby defining the non-adjusted region.

34. The method of claim 33, further comprising processing any remaining nodes by three-dimensional interpolation.

35. The method of claim 34, further comprising processing any remaining nodes by six-weight interpolation, wherein weight for each point is computed based on the distance or color difference of the point to the point to be processed.
